(19) United States
(12) Patent Application Publication
(10) Pub. No.: US 2025/0165693 A1
(43) Pub. Date: May 22, 2025

(54) MASK LAYOUT DESIGN METHOD AND MASK MANUFACTURING METHOD COMPRISING THE DESIGN METHOD

(71) Applicant: Samsung Electronics Co., Ltd., Suwon-si (KR)

(72) Inventors: Sangchul YEO, Suwon-si (KR); Jaewon YANG, Suwon-si (KR); Seungju SHIN, Suwon-si (KR)

(73) Assignee: Samsung Electronics Co., Ltd., Suwon-si (KR)

(21) Appl. No.: 18/752,925

(22) Filed: Jun. 25, 2024

(30) Foreign Application Priority Data
Nov. 20, 2023 (KR) 10-2023-0161442

(51) Int. Cl. G06F 30/392

(52) U.S. Cl. CPC G06F 30/392

(57) ABSTRACT

Provided is a mask layout design method including acquiring a plurality of unique patterns, clustering and sampling the plurality of unique patterns, and inspecting the plurality of unique patterns which have been clustered and sampled, wherein the clustering and sampling of the plurality of unique patterns is performed based on symmetry of the plurality of unique patterns.

### CROSS-REFERENCE TO RELATED APPLICATION

This application is based on and claims priority under 35 U.S.C. § 119 to Korean Patent Application No. 10-2023-0161442, filed on Nov. 20, 2023, in the Korean Intellectual Property Office, the disclosure of which is incorporated by reference herein in its entirety.

### BACKGROUND

The inventive concepts relate to a unique pattern, and in particular, to a mask layout design method and a mask manufacturing method including the design method.

In a semiconductor process, a photolithography process using an extreme ultraviolet lithography (EUV) mask may be performed to form a fine pattern on a semiconductor substrate such as a wafer. When defined in a simple manner, the EUV mask may be referred to as a pattern transfer body in which a pattern shape of an opaque material is formed on a transparent base material. To briefly explain the manufacturing process of EUV masks, first, the required circuit is designed, the layout for the circuit is designed, and then the design data for EUV masks obtained through Optical Proximity Correction (OPC) is delivered as Mask Tape-Out (MTO) design data. Thereafter, based on MTO design data, mask data preparation (MDP) may be performed, and an EUV mask may be manufactured by performing a front end of line (FEOL) such as an exposure process and a back end of line (BEOL) such as a defect inspection.

### SUMMARY

The inventive concepts provide a mask layout design method in which the number of pieces of sample data is reduced through clustering and sampling, and a mask manufacturing method including the design method.

In addition, the task to be solved by the technical idea of the inventive concepts is not limited to the above-mentioned task, and other tasks not mentioned above may be clearly understood by those of ordinary skill in the art from the following description.

According to an aspect of the inventive concepts, there is provided a mask layout design method including acquiring a plurality of unique patterns from a layout, clustering and sampling the plurality of unique patterns base don a symmetry of the plurality of unique patterns, and inspecting the plurality of unique patterns which have been clustered and sampled.

According to another aspect of the inventive concepts, there is provided a mask layout design method including receiving a layout, extracting a plurality of unique patterns of the layout, clustering and sampling the plurality of unique patterns, and inspecting the plurality of unique patterns which have been clustered and sampled, wherein the clustering and sampling of the plurality of unique patterns includes generating a plurality of analysis groups from the plurality of unique patterns, determining a feature vector of each of the plurality of analysis groups, grouping the plurality of analysis groups based on the feature vector, and selecting a representative analysis group for each of the grouped analysis groups, and wherein the grouping of the plurality of analysis groups based on dihedral symmetry.

According to another aspect of the inventive concepts, there is provided a mask manufacturing method including performing a mask layout design method, performing Optical Proximity Correction (OPC) on a final layout obtained through the mask layout design method, transferring data of an OPC-undergone layout as Mask Tape-Out (MTO) design data, preparing mask data based on the MTO design data, and exposing a substrate for a mask based on the mask data, wherein the performing of a mask layout design method includes acquiring a layout, extracting a plurality of unique patterns of the layout, clustering and sampling the plurality of unique patterns based on symmetry of the plurality of unique patterns, and inspecting the plurality of unique patterns which have been clustered and sampled.

### BRIEF DESCRIPTION OF THE DRAWINGS

Embodiments of the inventive concepts will be more clearly understood from the following detailed description taken in conjunction with the accompanying drawings in which:

FIG. 1 is a flowchart illustrating a mask layout design method according to at least one embodiment;

FIG. 2 is a flowchart illustrating a method of performing clustering and sampling on a plurality of unique patterns, according to at least one embodiment;

FIG. 3 is a conceptual diagram showing analysis groups according to at least one embodiment;

FIG. 4 is a conceptual diagram illustrating analysis groups having D2 symmetry, according to at least one embodiment;

FIG. 5 is a conceptual diagram illustrating analysis groups having D4 symmetry, according to at least one embodiment;

FIG. 6 is a graph illustrating a method for selecting a representative analysis group from one grouped analysis group, according to at least one embodiment; and

FIG. 7 is a flowchart illustrating a mask manufacturing method including a mask layout design method according to at least one embodiment.

### DETAILED DESCRIPTION OF THE EMBODIMENTS

Hereinafter, embodiments of the inventive concepts will be described in detail with reference to the accompanying drawings. The same reference numerals are used for the same components in the drawings, and redundant descriptions thereof are omitted. Further, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometric term.

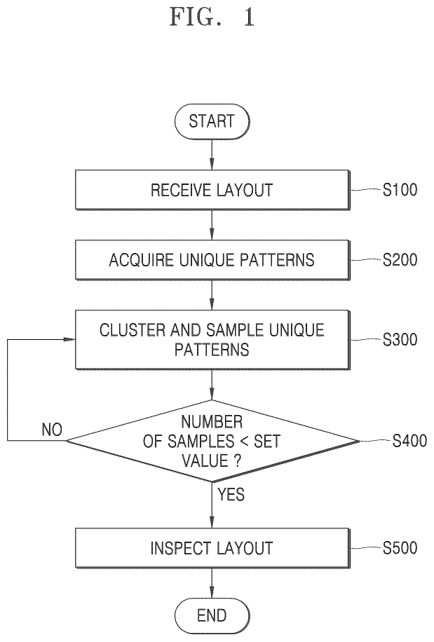

FIG. 1 is a flowchart illustrating a mask layout design method according to at least one embodiment.

Referring to FIG. 1, first, a layout of a semiconductor device may be received (S100). For example, data for the layout may be input. In at least one example, the layout may have a vector graphics format, such as a graphic design system (GDS), but, the data for the layout is not limited to the file format described above.

In order to manufacture a semiconductor device, circuit patterns constituting the semiconductor device should be formed. In addition, circuit patterns of a semiconductor device may be formed through a process of transferring a pattern on a mask to a substrate such as a wafer through an exposure process. Therefore, a layout of the patterns on the mask corresponding to the circuit patterns of the semiconductor device should be designed. The layout may be a layout of a semiconductor chip.

In at least one embodiment, the layout may be a target layout that is desired to be obtained during (or after) an After Cleaning Inspection (ACI). In other words, the layout may be a target layout (target ACI) desired to be obtained from the ACI. The ACI may mean an inspection after an etching process for substantially forming a pattern on a substrate.

In at least one embodiment, the layout may be a target layout of a photoresist desired to be obtained during (or after) an After Development Inspection (ADI). The ADI refers to inspection after a photo process for forming a photoresist pattern on a substrate, and the photo process may include an exposure process and a development process.

In at least one embodiment, the layout may be a layout of a photomask.

The layout may include a plurality of patterns. For example, the plurality of patterns may include at least one of a polygonal shape, a circular shape, and/or atypical or amorphous shape. Hereinafter, a case where a plurality of patterns include a polygonal shape (e.g., a line and space shape) will be described as an example.

Thereafter, a plurality of unique patterns may be extracted from the layout (S200). That is, the unique patterns may be obtained. The unique pattern may refer to a pattern that represents a repeated pattern and is distinguished from other patterns, from among a plurality of patterns included in the layout.

A method of extracting the unique pattern may be performed by unique pattern extraction and/or pattern matching. Unique pattern extraction may include a process of uniformly arranging the layout in a two-dimensional grid and determining the uniqueness of the pattern.

Thereafter, a pattern having uniqueness may be extracted as a representative pattern and stored as a hash code. Here, the hash code refers to a bit string outputted as an output of a hash function. The hash function is a function that maps data of an arbitrary length to data of a fixed length, and a value obtained by the hash function is referred to as a hash code, or simply a hash. The hash function is used in a data structure called a hash table and may be widely used in computer software for very fast data retrieval.

The pattern matching may refer to a method of extracting a corresponding pattern as a representative pattern by applying a preset pattern to the layout. In another embodiment, the pattern matching method may be used instead of a unique pattern extraction method, or may be used in conjunction with a unique pattern extraction method.

Thereafter, clustering and sampling for the plurality of unique patterns may be performed (S300). Here, clustering the plurality of unique patterns may mean a technique of grouping similar unique patterns. As will be described later, when a plurality of unique patterns are clustered, the number of pieces of sample data to be measured decreases, thereby increasing the reliability of the mask layout. Sampling may mean a technique of extracting some data from a specific data group. For example, for a clustered unique pattern, a representative unique pattern may be sampled.

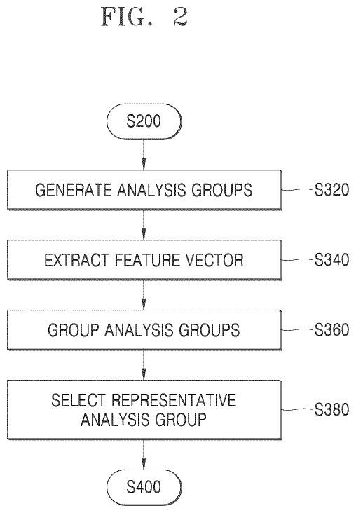

An example method of clustering and sampling a plurality of unique patterns is described in detail with reference to FIGS. 2 to 6.

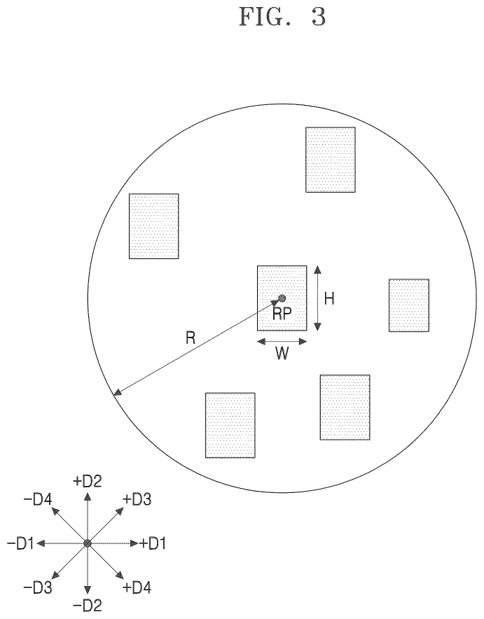

FIG. 2 is a flowchart illustrating a method of performing clustering and sampling on a plurality of unique patterns according to at least one embodiment; FIG. 3 is a conceptual diagram showing analysis groups according to at least one embodiment; Description will be made with reference to FIGS. 2 and 3 together with FIG. 1.

Referring to FIGS. 2 and 3, first, a plurality of analysis groups for a plurality of unique patterns may be generated (S320). The analysis groups may include a pattern within a constant radius R. The analysis groups may be data groups measured by measurement equipment later. For example, the constant radius R may be less than or equal to about 1 micrometer. In addition, the specific pattern serving as a reference may be determined to be located at a reference point (RP).

Thereafter, a feature vector for each of the plurality of analysis groups may be extracted (S340). The feature vector is a vector including data for the plurality of analysis groups, and may be used to cluster and sample the plurality of unique patterns. Here, the feature vector may include data on geometric features of a plurality of patterns.

The feature vector may include a width W and a height H of a pattern arranged at a reference point. The feature vector also includes at least one of: a distance from a reference point RP to a pattern closest in a positive (+) first direction; a distance to a pattern closest in a negative (−) first direction; a distance to a pattern closest in a positive (+) second direction; and a distance to a pattern closest in a negative (−) second direction. In addition, the feature vector includes at least one of: a distance from the reference point RP to a pattern closest in a positive (+) third direction; a distance to a pattern closest in a negative (−) third direction; a distance to a pattern closest in a positive (+) fourth direction; and a distance to a pattern closest in a negative (−) fourth direction. However, the feature vector included in the unique pattern is not limited thereto, and may include various feature vectors.

Hereafter, for clarity, a direction parallel to a main surface of the layout may be referred to as a horizontal direction, and a direction perpendicular to the horizontal direction may be referred to as a vertical direction. For example, each of the first to fourth directions D1, D2, D3, and D4 may be referred to as horizontal directions. The first direction (D1 direction) and the second direction (D2 direction) may be orthogonal to each other, and the third direction (D3 direction) and the fourth direction (D4 direction) may be orthogonal to each other. The third direction (D3 direction) and the fourth direction (D4 direction) may be oblique to the first direction (D1 direction) and the second direction (D2 direction). In some embodiments, the third direction (D3 direction) and the fourth direction (D4 direction) may form 45 degrees with the first direction (D1 direction) and the second direction (D2 direction). However, in some other embodiments, the third direction (D3 direction) and the fourth direction (D4 direction) may form other degrees with the first direction (D1 direction) and the second direction (D2 direction).

Thereafter, the plurality of analysis groups may be grouped based on the symmetry of the analysis groups (S360). For example, based on the dihedral symmetry of the analysis groups, the plurality of analysis groups may be grouped. Dihedral symmetry is a type of symmetry, and may have rotational symmetry and mirror symmetry characteristics. Rotational symmetry may mean a characteristic having the same shape when a target material rotates by a specific angle. For example, a square has a 4-fold rotational center. In addition, mirror symmetry can mean that the mirror image of the target material has the same shape as the target material. For example, a square has four 2-fold mirror axis bisecting the four sides and the four corners of the square, respectively. Similarly, a pinwheel may have rotational symmetry, but lack mirror symmetry; and an isosceles triangle may have mirror symmetry but lack rotational symmetry. Dihedral symmetry may be expressed as n-th-degree (Dn) symmetry if there are n equal parts (n is a natural number) that may divide an object by rotation. In the case of Dn symmetry, when the target object is rotated by

$$\frac{2 π}{n} rad ( \frac{360 °}{n} ) ,$$

the shape of the rotated target object may have the same shape as an original shape of the target object.

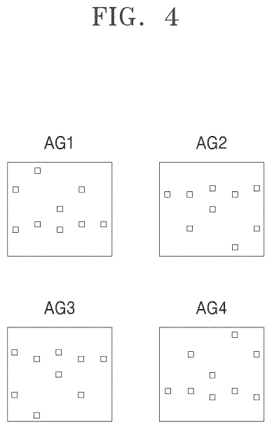

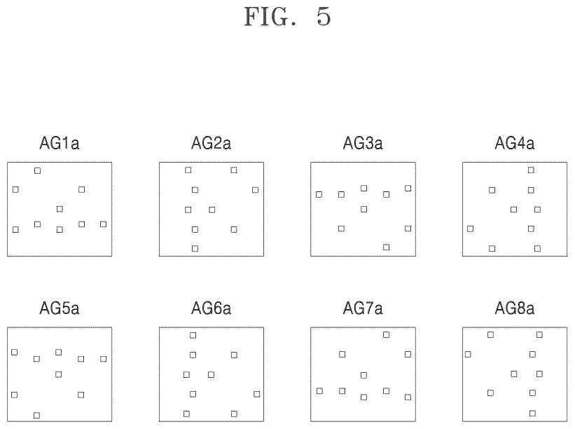

For example, dihedral symmetry may include D2 symmetry, D4 symmetry, and D6 symmetry. For example, a rectangle may be an example of D2 symmetry, and a square may be an example of D4 symmetry. In addition, a regular hexagon may be an example of D6 symmetry. When a rectangle is rotated by π rad (180°) in the original shape, the rotated rectangle may have the same shape as the original shape. The analysis group having the D2 symmetry and the D4 symmetry will be described in more detail with reference to FIGS. 4 and 5.

FIG. 4 is a conceptual diagram illustrating analysis groups having second degree (D2) symmetry according to at least one embodiment, and FIG. 5 is a conceptual diagram illustrating analysis groups having fourth degree (D4) symmetry according to at least one embodiment. Description will be made with reference to FIGS. 4 and 5 together with FIGS. 1 to 3.

Referring to FIGS. 4 and 5, as described above, D2 symmetry may mean a case in which there are two equal parts in which an object may be divided by rotation, and D4 symmetry may mean a case in which there are four equal parts in which an object may be divided by rotation. Therefore, since there are n rotational symmetries and two mirror symmetries exist for each rotational symmetry, an analysis group with Dn symmetry may include 2n individual symmetry elements. That is, D2 symmetry may include four individual symmetry elements, and D4 symmetry may include eight individual symmetry elements. In FIGS. 4 and 5, the unique patterns are simply shown in a square shape.

FIG. 4 shows four first to fourth analysis groups AG1, AG2, AG3, and AG4 having a D2 symmetrical relationship. That is, the three second to fourth analysis groups AG2, AG3, and AG4 of FIG. 4 may each represent individual symmetry elements of D2 symmetry with regards to the first analysis group AG1. In more detail, when the first analysis group AG1 is rotated by 180°, a second analysis group AG2 may be obtained. In addition, when the first analysis group AG1 is rotated to be mirror-symmetric, the third analysis group AG3 may be obtained, and when the second analysis group AG2 is rotated to be mirror-symmetric, the fourth analysis group AG4 may be obtained. That is, the first analysis group AG1 and the third analysis group AG3 may have a mirror image relationship with each other, and the second analysis group AG2 and the fourth analysis group AG4 may have a mirror image relationship with each other.

FIG. 5 shows eight first to eighth analysis groups AG1a, AG2a, AG3a, AG4a, AG5a, AG6a, AG7a, and AG8a in a D4 symmetrical relationship. That is, the seven second to eighth analysis groups AG1a, AG2a, AG3a, AG4a, AG5a, AG6a, AG7a, and AG8a of FIG. 5 may represent individual symmetry elements of D4 symmetry with regards to the first analysis group AG1a. For example, when the first analysis group AG1a is rotated by 90°, a second analysis group AG2a may be obtained. In addition, when the first analysis group AG1a is rotated 180° clockwise, the third analysis group AG3a may be obtained. In addition, when the first analysis group AG1a is rotated 270° clockwise, the fourth analysis group AG4a may be obtained. In addition, when the first analysis group AG1a is rotated to be mirror-symmetric, the fifth analysis group AG5a may be obtained, and when the second analysis group AG2a is rotated to be mirror-symmetric, the sixth analysis group AG6a may be obtained. In addition, when the third analysis group AG3a is rotated to be mirror-symmetric, the seventh analysis group AG7a may be obtained, and when the fourth analysis group AG4a is rotated to be mirror-symmetric, the eighth analysis group AG8a may be obtained. That is, the first analysis group AG1a and the fifth analysis group AG5a may have a mirror image relationship with each other, and the second analysis group AG2a and the sixth analysis group AG6a may have a mirror image relationship with each other. In addition, the third analysis group AG3a and the seventh analysis group AG7a may have a mirror image relationship with each other, and the fourth analysis group AG4a and the eighth analysis group AG8a may have a mirror image relationship with each other.

Referring back to FIG. 2, after the plurality of analysis groups are grouped (S360), one analysis group from among the grouped analysis groups may be selected as a representative analysis group (S380). For example, the first to eighth analysis groups AG1a, AG2a, AG3a, AG4a, AG5a, AG6a, AG7a, and AG8a of FIG. 5 in a D4 symmetrical relationship will be described as an example.

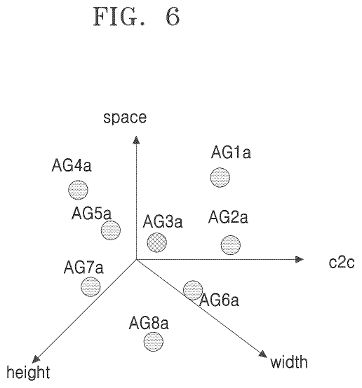

The method of selecting the representative analysis group may include a step in which each of the first to eighth analysis groups AG1a, AG2a, AG3a, AG4a, AG5a, AG6a, AG7a, and AG8a is arranged in a vector space. A process of expressing each of the first to eighth analysis groups AG1a, AG2a, AG3a, AG4a, AG5a, AG6a, AG7a, and AG8a in the vector space will be described with reference to FIG. 6.

FIG. 6 is a graph illustrating a method for selecting a representative analysis group from one grouped analysis group according to at least one embodiment; and In the graph of FIG. 6, height represents the height of a pattern arranged at a reference point RP, width represents the width of the pattern arranged at the reference point RP, space represents the distance from the pattern arranged at the reference point RP to the vector closest to each of the first and second directions D1 and D2, and c2c represents the distance from the pattern arranged at the reference point RP to the vector closest to each of the third and fourth directions D3 and D4. Description will be made with reference to FIG. 6 together with FIGS. 3 to 5.

Referring to FIG. 6, as described above, the vector space may have a variable of a feature vector as a dimension. For example, the vector space may have a width of a pattern arranged at the reference point RP, a height of the pattern arranged at the reference point RP, a distance from the pattern arranged at the reference point RP to the vector closest to each of the first and second directions D1 and D2, and/or a distance from the pattern arranged at the reference point RP to the vector closest to each of the third and fourth directions D3 and D4 as a variable (e.g., dimension). An analysis group closest to the origin of the vector space from among the first to eighth analysis groups AG1a, AG2a, AG3a, AG4a, AG5a, AG6a, AG7a, and AG8a may be selected as a representative analysis group. For example, in FIG. 6, since the third analysis group AG3a is closest to the origin of the vector space, the third analysis group AG3a may be selected as the representative analysis group. The analysis group closest to the origin of the vector space may mean a process of selecting a combination having the smallest sum of squares of values of each feature.

That is, in the case of D2 symmetry, the first to fourth analysis groups AG1, AG2, AG3, and AG4 may be grouped into one analysis group, and in the case of D4 symmetry, the first to eighth analysis groups AG1a, AG2a, AG3a, AG4a, AG5a, AG6a, AG7a, and AG8a may be grouped into one analysis group. Therefore, as will be described in detail later, the number of analysis groups (e.g., sample data) to be simulated decreases, so that patterns in the layout may be easily inspected.

In addition, the grouping of the plurality of analysis groups in operation S360 may be an example of a clustering technique, and the operation S380 of selecting a representative analysis group from the grouped analysis group may be an example of a sampling technique.

Returning back to FIG. 1, it is determined whether the number of pieces of clustered and sampled sample data is less than or equal to a set value (S400). That is, whether the number of clustered and sampled unique patterns and/or the number of grouped analysis groups is less than or equal to a set value is determined. The set value may be equal to the measurement capacity of measurement equipment when the measurement equipment measures the analysis group later. In at least one embodiment, the set value may be a preset threshold and may be less than the measurement capacity of the measurement equipment when the measurement equipment measures the unique pattern later. The measuring equipment may include Nano Geometry Research (NGR) equipment, Scanning Electron Microscope (SEM), and/or the like.

When the number of unique patterns of the sampled analysis group is less than or equal to a set value (Yes), the clustered and sampled unique patterns may be measured by the measurement equipment by proceeding to operation S500. Conversely, when the number of unique patterns of the sampled analysis group is greater than the set value, an additional clustering and sampling operation may be performed by proceeding to operation S300.

Thereafter, the layout may be inspected (S500). Here, the clustered and sampled unique patterns may be measured by NGR equipment and/or a SEM. Thereafter, the layout may be inspected through simulation. When there is an error in the inspected layout, the design rule of the layout may be changed to select a final layout. Conversely, when there is no error in the inspected layout, the layout may be selected as a final layout.

In at least one embodiment, the steps of FIG. 1 may be implemented by processing circuitry such as hardware, software, or a combination thereof configured to perform a specific function. For example, the processing circuitry more specifically may include (and/or be included in), but is not limited to, a central processing unit (CPU), an arithmetic logic unit (ALU), a digital signal processor, a microcomputer, a field programmable gate array (FPGA), and programmable logic unit, a microprocessor, application-specific integrated circuit (ASIC), etc.

Therefore, as described above, a method of clustering and sampling a plurality of unique patterns and a method of designing a mask layout are described with reference to FIGS. 1 to 6. The mask layout design method according to the inventive concepts may include a method of grouping a plurality of analysis groups in consideration of dihedral symmetry. Accordingly, the number of analysis groups to be analyzed (e.g., the number of pieces of sample data) may be reduced, and analysis groups with high representativeness may be extracted. Therefore, the reliability of the mask layout design method may increase.

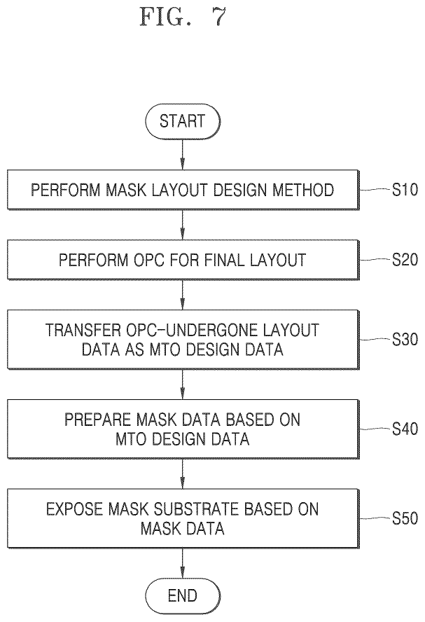

FIG. 7 is a flowchart illustrating a mask manufacturing method including a mask layout design method according to at least one embodiment. Description will be made with reference to FIG. 7 together with FIGS. 1 to 6.

Referring to FIG. 7, a mask manufacturing method including a mask layout design method of this embodiment (hereinafter, simply referred to as the mask manufacturing method) first performs the mask layout design method (S10). The mask layout design method (S10) is as described above with reference to the mask layout design method of FIG. 1. That is, the mask layout design method (S10) may include receiving a layout (S100), extracting a plurality of unique patterns (S200), clustering and sampling the plurality of unique patterns (S300), comparing the number of analysis groups with a set value (S400), and inspecting the layout (S500).

Thereafter, Optical Proximity Correction (OPC) is performed on the final layout obtained by performing the mask layout design method (S20). As the pattern is miniaturized, an optical proximity effect (OPE) due to an influence between neighboring patterns occurs during an exposure process. In order to overcome the problem, OPC may be performed to suppress occurrence of the OPE by correcting the mask layout. The OPC may include processes of generating an optical image for the corresponding pattern, generating an OPC model, and obtaining an image or data for the mask layout through simulation using the OPC model.

The overall description of OPC is as follows. OPC is largely divided into two categories: one is a rule-based OPC, and the other is a simulation-based or model-based OPC. The OPC in the mask layout design method according to the embodiment may be, for example, a model-based OPC. The model-based OPC may be advantageous in terms of time and cost because it uses only the measurement results of representative patterns without the need to measure all of the large amounts of test patterns. Meanwhile, OPC may include not only a modification of the mask layout, but also a method of adding sub-lithographic features called serifs onto the corner of the pattern, or a method of adding sub-resolution assist features (SARFs) such as scattering bars.

In the case of the OPC, basic data for the OPC is first prepared. Here, the basic data may include data on the shape of patterns of a sample, the location of the patterns, the type of measurement such as measurement for space or line of the pattern, basic measurement values, and the like. In addition, the basic data includes information such as thickness, refractive index, and dielectric constant for a photoresist (PR), and may include a source map for the shape of an illumination system. Of course, the basic data is not limited to the data illustrated above.

After preparing the basic data, an optical OPC model is generated. The generation of the optical OPC model may include optimization of a defocus stand (DS) position and a best focus (BF) position in the exposure process. In addition, the generation of the optical OPC model may include the generation of an optical image considering the phenomenon of the diffraction of light or an optical state of an exposure facility itself. Of course, the generation of the optical OPC model is not limited to the contents described above. For example, the generation of the optical OPC model may include various contents related to optical phenomena in the exposure process.

After generating the optical OPC model, an OPC model for the PR is generated. The generation of the OPC model for the PR may include optimization of the threshold of PR. Here, the threshold value of the PR refers to a threshold value at which a chemical change occurs in the exposure process, and for example, the threshold value may be given as the intensity of the exposure light. The generation of the OPC model for the PR may also include selecting an appropriate model form from several PR model forms.

The optical OPC model and the OPC model for PR are combined and generally referred to as the OPC model. After generating the OPC model, the simulation is repeated using the OPC model. The simulation may be performed until a predetermined (or otherwise determined) condition is satisfied. For example, Root Mean Square (RMS), Edge Placement Error (EPE), and reference repetition number of times for CD errors may be used as repetition conditions for simulation. In the mask layout design method according to the at least one embodiment, OPC layout images or data may be obtained through simulation using such an OPC model.

Thereafter, the OPC-undergone layout data is transmitted as MTO design data to a mask manufacturing team (S30). In general, MTO may mean handing over the final mask data obtained through the OPC method to the mask manufacturing team and requesting for mask manufacturing. Thus, the MTO design data may eventually be substantially the same as the OPC-undergone layout data. Such MTO design data may have a graphic data format used in electronic design automation (EDA) software or the like. For example, MTO design data may have data formats such as Graphic Data System II (GDS2) and Open Artwork System Interchange Standard (OASIS).

Thereafter, mask data preparation (MDP) is performed (S40). Preparation of mask data may include, for example, i) format conversion called fracturing, ii) augmentation of barcodes for mechanical reading, standard mask patterns for inspection, job-deck, and/or the like, and iii) verification according to automatic and manual systems. Here, the job-deck may mean creating a text file related to a series of commands such as arrangement information of multi-mask files, a reference dose, and an exposure speed or method.

Meanwhile, format conversion (e.g., fracturing) may mean a process of fracturing MTO design data for each area and changing the fractured MTO design data to a format for an electron beam exposure machine. The fracturing may include, for example, data manipulation such as scaling, data sizing, data rotation, pattern reflection, and color inversion. In the process of conversion through fracturing, data for numerous systematic errors that may occur anywhere in the process of transferring design data to an image on a wafer may be corrected. The data correction process for the system errors is called a mask process correction (MPC), and may include, for example, an operation of increasing the precision of line width adjustment and pattern arrangement called CD adjustment. Thus, the fracturing may contribute to the improvement of the quality of the final mask and may also be a process performed in advance to correct the mask process. Here, systematic errors may be caused by distortions occurring in exposure processes, mask development and etching processes, wafer imaging processes, and the like.

Meanwhile, the preparation of the mask data may include an MPC. As described above, the MPC refers to a process of correcting an error occurring during the exposure process, that is, a systematic error. Here, the exposure process may be a concept including electron beam writing, development, etching, baking, and/or the like as a whole. In addition, data processing may be performed before the exposure process. The data processing is a pre-processing process for a kind of mask data, and may include a grammar check for mask data, an exposure time prediction, and the like. Through the preparation of such mask data, E-beam data to expose the mask substrate may be generated.

After preparing the mask data, the mask substrate is exposed using the mask data, that is, the E-beam data (S50). Here, exposure may mean, for example, E-beam writing. Here, E-beam writing may be carried out using, for example, a Gray Writing method using a Multi-Beam Mask Writer (MBMW). In addition, electron beam writing may be performed using a variable shape beam (VSB) exposure machine.

Meanwhile, after the mask data preparation operation, a process of converting E-beam data into pixel data before the exposure process may be performed. The pixel data is data directly used for actual exposure, and may include data on a shape to be exposed and data on the dose of the E-beam allocated to each piece of the data on the shape. Here, the data on the shape may be bit-map data in which shape data, which is vector data, is converted through rasterization or the like.

After the exposure process, a series of processes may be performed to complete a mask. A series of processes may include, for example, processes such as development, etching, and cleaning. In addition, a series of processes for mask manufacturing may include measurement processes, defect inspection, or defect repair processes. In addition, a pellicle application process may be included. Here, if it is confirmed that there are no contaminants or chemical stains through final cleaning and inspection, the pellicle application process may mean the process of attaching a pellicle to protect the mask surface from subsequent contamination during the delivery of the mask and the available life of the mask. In at least one embodiment, the steps of FIG. 7 may be implemented by processing circuitry included in and/or configured to control a semiconductor processing apparatus.

While the inventive concepts have been particularly shown and described with reference to embodiments thereof, it will be understood that various changes in form and details may be made therein without departing from the spirit and scope of the following claims.

What is claimed is:

1. A mask layout design method comprising:
acquiring a plurality of unique patterns from a layout;
clustering and sampling the plurality of unique patterns based on symmetry of the plurality of unique patterns; and
inspecting the plurality of unique patterns which have been clustered and sampled.

2. The mask layout design method of claim 1, wherein the clustering and sampling of the plurality of unique patterns comprises:
generating a plurality of analysis groups from the plurality of unique patterns;
determining a feature vector of each of the plurality of analysis groups;
grouping the plurality of analysis groups on based on the feature vectors; and
selecting a representative analysis group for each of the grouped analysis groups.

3. The mask layout design method of claim 2, wherein the feature vector comprises information of a geometry feature of the plurality of unique patterns.

4. The mask layout design method of claim 2, wherein the feature vector is based on a dimension of a first pattern arranged at a reference point of each of the plurality of analysis groups and a second pattern spaced apart from the reference point.

5. The mask layout design method of claim 2, wherein the grouping of the plurality of analysis groups is based on dihedral symmetry.

6. The mask layout design method of claim 5, wherein the dihedral symmetry includes at least one of second degree D2 symmetry or fourth degree D4 symmetry.

7. The mask layout design method of claim 2, wherein the selecting of the representative analysis group comprises:
arranging each of the grouped analysis groups in a vector space; and
selecting, as the representative analysis group, an analysis group that is closest to an origin of the vector space.

8. A mask layout design method comprising:
receiving a layout;
extracting a plurality of unique patterns of the layout;
clustering and sampling the plurality of unique patterns; and
inspecting the plurality of unique patterns which have been clustered and sampled,
wherein the clustering and sampling of the plurality of unique patterns comprises
generating a plurality of analysis groups from the plurality of unique patterns,
determining a feature vector of each of the plurality of analysis groups,
grouping the plurality of analysis groups based on the feature vector, and
selecting a representative analysis group for each of the grouped analysis groups, and
wherein the grouping of the plurality of analysis groups is based on dihedral symmetry.

9. The mask layout design method of claim 8, wherein the extracting of the unique pattern comprises at least one of a unique pattern extraction technique or a pattern matching technique.

10. The mask layout design method of claim 8, wherein the feature vector comprises at least one of a width of a reference pattern at a reference point of the plurality of analysis groups; a height of the reference pattern arranged at the reference point; a distance from the reference point to a pattern closest in a positive (+) first direction; a distance from the reference point to a pattern closest in a negative (−) first direction; a distance from the reference point to a pattern closest in a positive (+) second direction; a distance from the reference point to a pattern closest in a negative (−) second direction; a distance from the reference point to a pattern closest in a positive (+) third direction; a distance from the reference point to a pattern closest in a negative (−) third direction; a distance from the reference point to a pattern closest in a positive (+) fourth direction; or a distance from the reference point to a pattern closest in a negative (−) fourth direction.

11. The mask layout design method of claim 8, wherein the layout has a Graphic Design System (GDS) format.

12. The mask layout design method of claim 8, wherein the selecting of the representative analysis group comprises
arranging each of the grouped analysis groups in a vector space; and
selecting, as the representative analysis group, an analysis group that is closest to an origin of the vector space, and
wherein the vector space has the feature vector as a variable.

13. The mask layout design method of claim 8, wherein a radius of each of the plurality of analysis groups is about 1 micrometer or less.

14. The mask layout design method of claim 8, wherein the layout includes at least one of a layout of a semiconductor chip, a target layout desired to be obtained from an after cleaning inspection (ACI), a layout of a photoresist, or a layout of a photomask.

15. The mask layout design method of claim 8, wherein the plurality of unique patterns include a plurality of polygon-shaped patterns.

16. The mask layout design method of claim 8, further comprising generating a final layout by changing a design rule of the layout.

17. A mask manufacturing method comprising:
performing a mask layout design method;
performing Optical Proximity Correction (OPC) on a final layout obtained through the mask layout design method;
transferring data of an OPC-undergone layout as Mask Tape Out (MTO) design data;
preparing mask data based on the MTO design data; and
exposing a substrate for a mask on the basis of the mask data,
wherein the performing of a mask layout design method comprises
acquiring a layout,
extracting a plurality of unique patterns of the layout,
clustering and sampling the plurality of unique patterns based on symmetry of the plurality of unique patterns, and
inspecting the plurality of unique patterns which have been clustered and sampled.

18. The mask manufacturing method of claim 17, wherein the clustering and sampling of the plurality of unique patterns comprises
generating a plurality of analysis groups including the plurality of unique patterns;
determining a feature vector of each of the plurality of analysis groups;
grouping the plurality of analysis groups based on of the feature vector; and
selecting a representative analysis group of each of the plurality of grouped analysis groups, and
wherein the selecting of the representative analysis group comprises
arranging each of the grouped analysis groups in a vector space; and
selecting an analysis group that is closest to an origin of the vector space as the representative analysis group.

19. The mask manufacturing method of claim 17, wherein the grouping of the plurality of analysis groups is performed on the basis of dihedral symmetry of the plurality of analysis groups.

20. The mask manufacturing method of claim 19, wherein the dihedral symmetry includes at least one of second degree (D2) symmetry or fourth degree (D4) symmetry.
